(19) United States
(12) Patent Application Publication
(10) Pub. No.: US 2026/0096350 A1
(43) Pub. Date: Apr. 2, 2026

(54) PIEZOELECTRIC ELEMENT AND LIQUID EJECTION HEAD

(71) Applicant: SEIKO EPSON CORPORATION, Tokyo (JP)

(72) Inventors: Nobuo OZAWA, CHINO-SHI (JP); Takatoshi YAMAZAKI, SHIOJIRI-SHI (JP); Toshihiro SHIMIZU, FUJIMI-MACHI (JP); Shunsuke YOSHIDA, MATSUMOTO-SHI (JP)

(21) Appl. No.: 19/343,346

(22) Filed: Sep. 29, 2025

(30) Foreign Application Priority Data
Sep. 30, 2024 (JP) 2024-170682

(51) Int. Cl. H10N 30/87; B41J 2/14; H10N 30/06; H10N 30/20; H10N 30/853

(52) U.S. Cl. CPC H10N 30/87; B41J 2/14233; H10N 30/06; H10N 30/2047; H10N 30/8554; B41J 2002/14258

(57) ABSTRACT

A piezoelectric element includes: a lower electrode, a piezoelectric layer including a perovskite-type composite oxide, and an upper electrode that are stacked in a stacking direction; and a first hydrogen absorption layer that absorbs hydrogen above or below the lower electrode in the stacking direction. In the piezoelectric element, the first hydrogen absorption layer is preferably provided between the lower electrode and the piezoelectric layer in the stacking direction.

The present application is based on, and claims priority from JP Application Serial Number 2024-170682, filed Sep. 30, 2024, the disclosure of which is hereby incorporated by reference herein in its entirety.

### BACKGROUND

### 1. Technical Field

The present disclosure relates to a piezoelectric element and a liquid ejection head.

### 2. Related Art

An image forming apparatus including a liquid ejection head that ejects a liquid such as ink onto a medium such as printing paper has been proposed. As the liquid ejection head, there is known a head which ejects a liquid filling a pressure chamber from a nozzle by vibrating a diaphragm constituting a wall surface of the pressure chamber using a piezoelectric element.

A piezoelectric element included in a liquid ejection head described in JP-A-2010-214800 includes a pair of electrodes and a piezoelectric layer interposed between the pair of electrodes. The piezoelectric layer has a perovskite structure such as PZT.

The piezoelectric layer described in JP-A-2010-214800 is formed of a plurality of layers formed by a sol-gel method. Each of the layers is formed by applying and drying a coating solution containing an organic compound to form a gelled precursor film, and then firing the precursor film. By repeating the formation and firing of the precursor film a plurality of times, the piezoelectric layer composed of a plurality of layers is formed.

In the piezoelectric element, it is known that a composition gradient occurs in each layer depending on the crystallization temperature of a material used. For example, when the piezoelectric layer is made of lead zirconate titanate, a large amount of titanium is likely to segregate at the interface where crystallization is likely to proceed rapidly due to the difference in crystallization temperature between lead titanate and lead zirconate. Therefore, in each layer, the composition may be different between the vicinity of the interface and the center of the layer. When such a composition gradient occurs, displacement characteristics of the piezoelectric element may be affected.

In addition, as a result of intensive studies, the present inventors have found that the hysteresis characteristics greatly change depending on the hydrogen content of the piezoelectric layer. In particular, it has been found that even in piezoelectric elements having the same composition gradient, hysteresis characteristics change depending on the hydrogen content. Further, hydrogen shows a strong tendency to enter from the lower electrode side.

When the hysteresis characteristics of piezoelectric elements change, a difference in displacement amount occurs between the piezoelectric elements. Therefore, it is necessary to adjust the difference by changing a driving voltage or a waveform for each piezoelectric element. Therefore, there is a problem of poor usability.

### SUMMARY

A piezoelectric element according to an aspect of the present disclosure is a piezoelectric element including: a lower electrode, a piezoelectric layer including a perovskite-type composite oxide, and an upper electrode that are stacked in a stacking direction; and a first hydrogen absorption layer that absorbs hydrogen above or below the lower electrode in the stacking direction.

A liquid ejection head according to an aspect of the present disclosure includes the piezoelectric element.

### BRIEF DESCRIPTION OF THE DRAWINGS

FIG. 1 is a schematic view illustrating a configuration of an image forming apparatus according to a first embodiment.

FIG. 2 is an exploded perspective view of a liquid ejection head illustrated in FIG. 1.

FIG. 3 is a cross-sectional view of a portion of the liquid ejection head illustrated in FIG. 1.

FIG. 4 is a cross-sectional view of a piezoelectric element illustrated in FIG. 3.

FIG. 5 is a cross-sectional view of the piezoelectric element illustrated in FIG. 3.

FIG. 6 is a diagram schematically illustrating the piezoelectric element illustrated in FIG. 4.

FIG. 7 is a graph showing measurement results for the piezoelectric element illustrated in FIG. 6 by a secondary ion mass spectrometer (SIMS).

FIG. 8 is a flowchart of a method of manufacturing the piezoelectric element of FIG. 6.

FIG. 9 is a diagram schematically illustrating a piezoelectric element of a first modification.

FIG. 10 is a diagram schematically illustrating a piezoelectric element of a second modification.

FIG. 11 is a cross-sectional view of a piezoelectric element of a third modification.

FIG. 12 is a graph showing measurement results for the piezoelectric element of the third modification by a secondary ion mass spectrometer.

FIG. 13 is a diagram schematically illustrating a piezoelectric element of a fourth modification.

### DESCRIPTION OF EMBODIMENTS

Preferred embodiments according to the present disclosure will be described with reference to the accompanying drawings below. In the drawings, the size or scale of each portion is different from the actual size or scale as appropriate, and some portions are schematically illustrated to facilitate understanding. Further, the scope of the present disclosure is not limited to these embodiments unless it is noted in the following description that the present disclosure is particularly limited. Further, the phrase “an element β on an element γ” is not limited to a configuration in which the element y and the element β are in direct contact with each other, and also includes a configuration in which the element γ and the element β are not in direct contact with each other. The phrase “the element γ is the same as the element β” means that the element γ needs only to be substantially the same as the element β, and includes a manufacturing error or the like. In addition, the phrase “an element α and an element β are stacked” means that the element α and the element β need only to be arranged in an up-down direction, irrespective of whether the element α and the element β are in direct contact with each other.

### 1. First Embodiment

### 1-1. Overall Configuration of Image Forming Apparatus 100

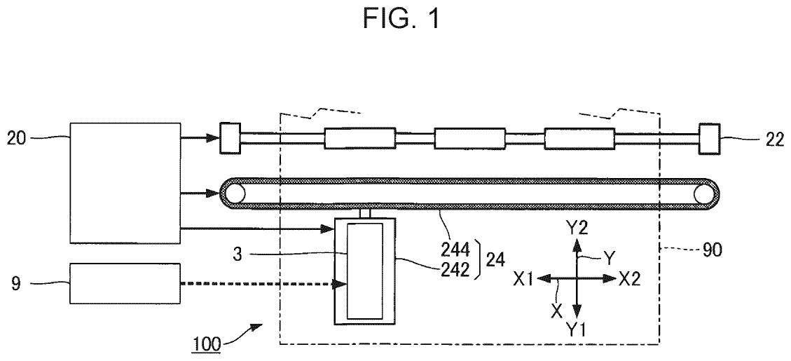

FIG. 1 is a schematic view illustrating a configuration of an image forming apparatus 100 according to a first embodiment. Hereinafter, for convenience of description, the description will be made by appropriately using an X axis, a Y axis, and a Z axis which are orthogonal to one another. In addition, one direction along the X axis is referred to as an X1 direction, and a direction opposite to the X1 direction is referred to as an X2 direction. Similarly, one direction along the Y axis is referred to as a Y1 direction, and a direction opposite to the Y1 direction is referred to as a Y2 direction. One direction along the Z axis is referred to as a Z1 direction, and a direction opposite to the Z1 direction is referred to as a Z2 direction. Viewing in a direction along the Z axis will be referred to as “in plan view.” The “stacking direction” is a direction along the Z axis. The Z axis is typically a vertical axis. The Z2 direction is upward, and the Z1 direction is downward. Meanwhile, the Z axis need not be the vertical axis. The X axis, the Y axis, and the Z axis are typically orthogonal to one another, but are not limited thereto, and need only to intersect one another at an angle within a range of, for example, 80° or more and 100° or less.

The image forming apparatus 100 of FIG. 1 is an ink jet printing apparatus that ejects ink, which is an example of a liquid, onto a medium 90. The medium 90 is typically printing paper, but a printing target of any material such as a resin film or a cloth is used as the medium 90. As illustrated in FIG. 1, a liquid container 9 that stores ink is installed in the image forming apparatus 100. For example, a cartridge attachable to and detachable from the image forming apparatus 100, a bag-shaped ink pack formed of a flexible film, or an ink tank that can be refilled with ink is used as the liquid container 9.

The image forming apparatus 100 includes a control unit 20, a medium transport mechanism 22, a moving mechanism 24, and a liquid ejection head 3. The control unit 20 includes, for example, one or a plurality of processing circuits such as a central processing unit (CPU) or a field programmable gate array (FPGA) and one or a plurality of storage circuits such as a semiconductor memory, and integrally controls each element of the image forming apparatus 100.

The medium transport mechanism 22 transports the medium 90 in a direction along the Y axis under control by the control unit 20. Further, the moving mechanism 24 reciprocates the liquid ejection head 3 along the X axis under control by the control unit 20. The moving mechanism 24 includes a substantially box-shaped transport body 242 that houses the liquid ejection head 3, and a transport belt 244 to which the transport body 242 is fixed. A configuration in which a plurality of liquid ejection heads 3 are mounted on the transport body 242 or a configuration in which the liquid container 9 is mounted on the transport body 242 together with the liquid ejection head 3 may be employed.

The liquid ejection head 3 ejects ink supplied from the liquid container 9 onto the medium 90 from a plurality of nozzles under control by the control unit 20. An image is formed on a surface of the medium 90 by each liquid ejection head 3 ejecting ink onto the medium 90 in parallel with the transport of the medium 90 by the medium transport mechanism 22 and the repeated reciprocation of the transport body 242.

The image forming apparatus 100 is of a serial head type in which the liquid ejection head 3 reciprocates on the medium 90. However, the image forming apparatus 100 may be of a line head type in which the liquid ejection head 3 is fixed.

### 1-2. Overall Configuration of Liquid Ejection Head 3

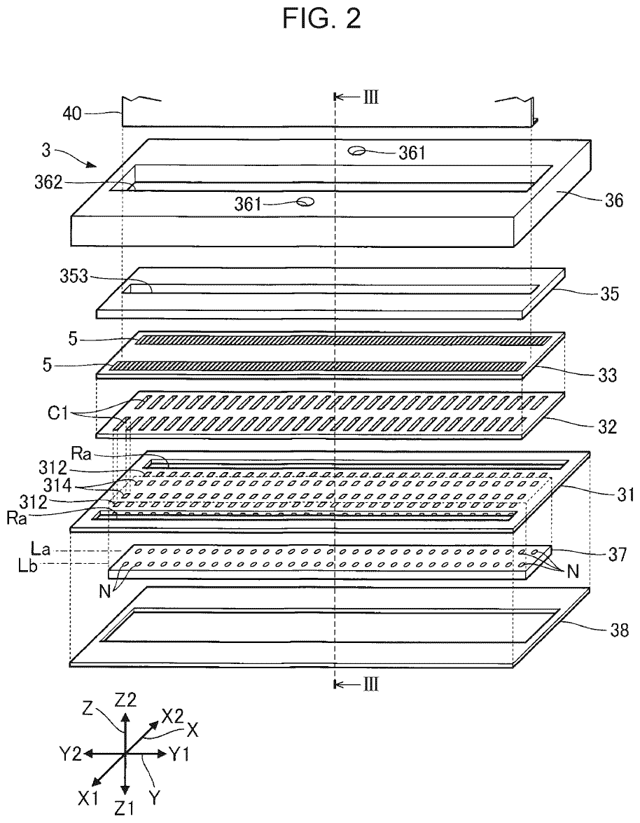

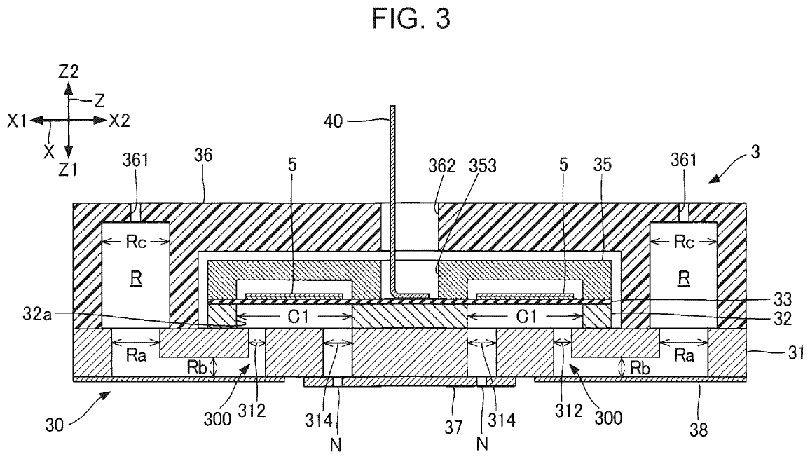

FIG. 2 is an exploded perspective view of the liquid ejection head 3 illustrated in FIG. 1. FIG. 3 is a cross-sectional view of a portion of the liquid ejection head illustrated in FIG. 1, taken along line III-III in FIG. 2. The cross-section illustrated in FIG. 3 is a cross-section parallel to an X-Z plane. Note that the Z axis is an axis in the direction in which ink is ejected by the liquid ejection head 3.

As illustrated in FIG. 2, the liquid ejection head 3 includes a plurality of nozzles N arranged along the Y axis. The plurality of nozzles N of the first embodiment is divided into a first row La and a second row Lb which are provided in parallel at an interval from each other along the X axis. Each of the first row La and the second row Lb is a set of a plurality of nozzles N linearly arranged along the Y axis. The liquid ejection head 3 has a structure in which the elements related to each nozzle N in the first row La and the elements related to each nozzle N in the second row Lb are disposed substantially in plane symmetry. In the following description, the elements corresponding to the first row La will be mainly described, and the description of the elements corresponding to the second row Lb will be appropriately omitted.

As illustrated in FIG. 2 and FIG. 3, the liquid ejection head 3 includes a flow path forming substrate 31, a pressure chamber substrate 32, a diaphragm 33, a nozzle plate 37, a vibration absorber 38, a plurality of piezoelectric elements 5, a sealing body 35, a housing 36, and a wiring board 40. Each of the flow path forming substrate 31, the pressure chamber substrate 32, the diaphragm 33, the nozzle plate 37, the vibration absorber 38, the sealing body 35, and the housing 36 is an elongated plate-shaped member along the Y axis. In addition, the nozzle plate 37, the flow path forming substrate 31, the pressure chamber substrate 32, the diaphragm 33, and the sealing body 35 are arranged in this order in the Z2 direction.

The nozzle plate 37 is a plate-like member in which the plurality of nozzles N is formed. Each of the nozzles N is a circular through-hole through which the ink is ejected. The nozzle plate 37 is bonded to a surface of the flow path forming substrate 31 in the Z1 direction by, for example, an adhesive.

The flow path forming substrate 31 forms a flow path through which ink flows. Specifically, in the flow path forming substrate 31, a space Ra, a relay liquid chamber Rb, a plurality of supply flow paths 312, and a plurality of communication flow paths 314 are formed. The space Ra is an opening formed in an elongated shape along the Y axis. Each of the supply flow paths 312 and the communication flow paths 314 is a through-hole formed for each nozzle N. Each of the communication flow paths 314 overlaps a corresponding nozzle N in plan view as seen from the Z1 direction. The relay liquid chamber Rb is a space formed in an elongated shape along the Y axis over the plurality of nozzles N, and allows the space Ra and the plurality of supply flow paths 312 to communicate with each other. The pressure chamber substrate 32 is bonded to a surface of the flow path forming substrate 31 in the Z2 direction with an adhesive.

A plurality of pressure chambers C1 is formed in the pressure chamber substrate 32. The ink to be ejected from the nozzles N is stored in the pressure chambers C1. Each pressure chamber C1 is a space located between the nozzle plate 37 and the diaphragm 33 and formed by an inner wall surface 32a of the pressure chamber substrate 32. The pressure chamber C1 is formed for each nozzle N. The pressure chamber C1 is an elongated space and extends in the X1 direction. The plurality of pressure chambers C1 is arranged along the Y axis. Each pressure chamber C1 communicates with the communication flow path 314 and the supply flow path 312. Therefore, the pressure chamber C1 communicates with the nozzle N via the communication flow path 314, and communicates with the space Ra via the supply flow path 312 and the relay liquid chamber Rb.

The nozzle plate 37, the flow path forming substrate 31, and the pressure chamber substrate 32 are manufactured by processing a single crystal substrate of silicon (Si) using a semiconductor manufacturing technique such as photolithography and etching. However, any known material and manufacturing method can be employed to manufacture the nozzle plate 37, the flow path forming substrate 31, and the pressure chamber substrate 32.

The diaphragm 33 is connected to a surface of the pressure chamber substrate 32 on the opposite side from the flow path forming substrate 31. The diaphragm 33 is disposed over the pressure chambers C1 and is elastically deformable. The diaphragm 33 is a plate-shaped member formed in an elongated rectangular shape along the Y axis in plan view. The diaphragm 33 and the pressure chamber substrate 32 may be integrally formed, or may be separately formed and bonded to each other with an adhesive or the like.

Each piezoelectric element 5 is formed on the surface of the diaphragm 33 on the opposite side from the pressure chamber C1. The piezoelectric element 5 is provided for each pressure chamber C1. The piezoelectric element 5 has an elongated shape along the X axis in plan view. The piezoelectric element 5 is a drive element that is driven by a drive signal applied thereto, and applies pressure to ink in the pressure chamber C1.

The sealing body 35 is bonded to the diaphragm 33 by, for example, an adhesive. The sealing body 35 is a structure that protects the plurality of piezoelectric elements 5 and reinforces the mechanical strength of the pressure chamber substrate 32 and the diaphragm 33. The sealing body 35 has recesses formed on a surface facing the diaphragm 33. The piezoelectric elements 5 are housed inside the recesses. The sealing body 35 has a space 353 into which the wiring board 40 is inserted.

The housing 36 is bonded to the flow path forming substrate 31 by, for example, an adhesive. The housing 36 is a case for storing ink to be supplied to the plurality of pressure chambers C1. The housing 36 is formed by injection molding of a resin material, for example. A space Rc, a supply port 361, and a space 362 are formed in the housing 36. The supply port 361 is a conduit through which ink is supplied from the liquid container 9, and communicates with the space Rc. The space Rc communicates with the space Ra of the flow path forming substrate 31. A space formed by the space Rc and the space Ra functions as a liquid storage chamber β that stores ink to be supplied to the plurality of pressure chambers C1. The ink supplied from the liquid container 9 and passing through the supply port 361 is stored in the liquid storage chamber R. The ink stored in the liquid storage chamber β branches from the relay liquid chamber Rb into each of the supply flow paths 312 and is supplied to the plurality of pressure chambers C1 in parallel. In addition, the space 362 overlaps the space 353 of the sealing body 35 in plan view. The wiring board 40 is inserted into the space 353 and the space 362.

The wiring board 40 is connected to the diaphragm 33. The wiring board 40 is a mounting component on which a plurality of wiring lines for electrically coupling the control unit 20 and the liquid ejection head 3 are formed. For example, a flexible substrate such as a flexible printed circuit (FPC) or a flexible flat cable (FFC) is preferably used as the wiring board 40. A drive signal for driving the piezoelectric elements 5 and a reference voltage are supplied to each piezoelectric element 5 from the wiring board 40.

In addition, the vibration absorber 38 is bonded to the surface of the flow path forming substrate 31 in the Z1 direction by, for example, an adhesive. The vibration absorber 38 is a flexible film constituting a wall surface of the space Ra and absorbs pressure fluctuations of the ink in the liquid storage chamber R.

In the liquid ejection head 3, when the piezoelectric elements 5 are flexurally deformed by application of a voltage, the diaphragm 33 is flexurally deformed, that is, vibrates, in a direction in which the volume of the pressure chambers C1 decreases. As a result, the pressure in the pressure chambers C1 changes, and the ink in the pressure chambers C1 is ejected from the nozzles N. After the ink ejection, the piezoelectric elements 5 are restored to the original position thereof.

In addition, although the liquid ejection head 3 includes all elements illustrated in FIG. 3, the constituent elements of the liquid ejection head 3 do not necessarily include all of the elements, and may further include additional elements.

### 1-3. Piezoelectric Element 5

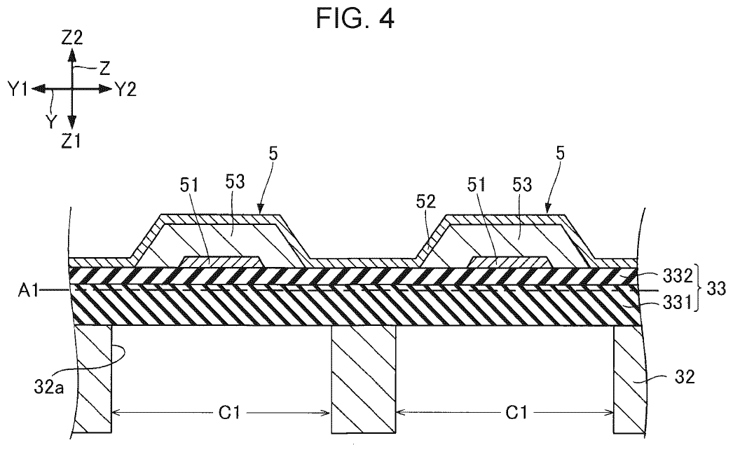

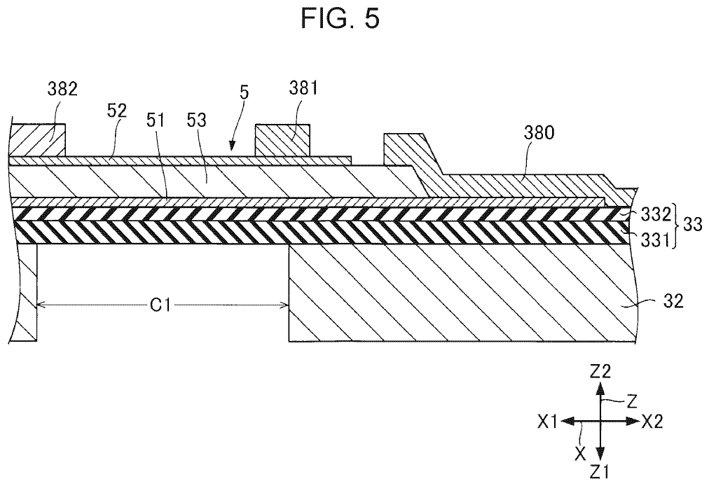

FIG. 4 and FIG. 5 are each a cross-sectional view illustrating the piezoelectric element 5 illustrated in FIG. 3. The cross section illustrated in FIG. 4 is a cross section parallel to the Y-Z plane. The cross section illustrated in FIG. 5 is a cross section parallel to the X-Z plane.

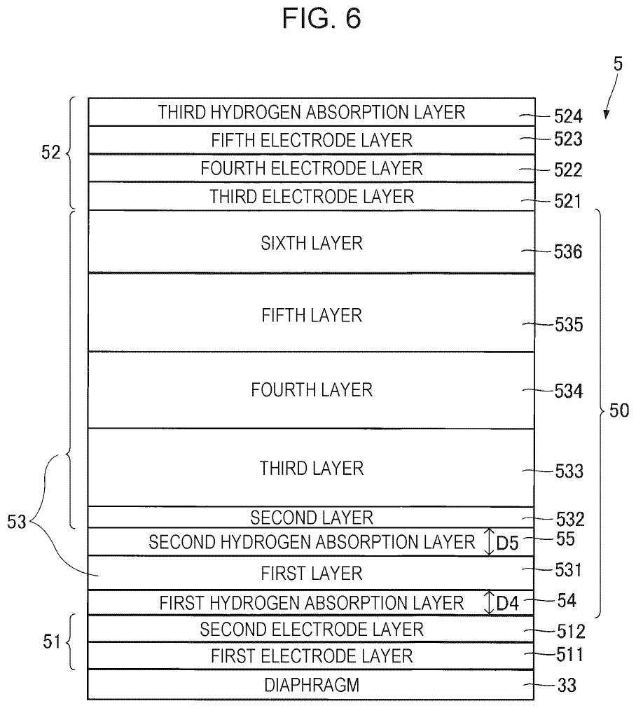

As shown in FIG. 4 and FIG. 5, the piezoelectric element 5 mainly includes a lower electrode 51, a piezoelectric layer 53, and an upper electrode 52. The lower electrode 51, the piezoelectric layer 53, and the upper electrode 52 are stacked in a direction along the Z axis which is a stacking direction. As will be described later, the piezoelectric element 5 further includes a first hydrogen absorption layer 54 and a second hydrogen absorption layer 55 as shown in FIG. 6. The piezoelectric layer 53, the first hydrogen absorption layer 54, and the second hydrogen absorption layer 55 may be collectively referred to as an intermediate layer 50 located between the lower electrode 51 and the upper electrode 52.

As shown in FIG. 4 and FIG. 5, the lower electrode 51 is provided above the diaphragm 33. The lower electrode 51 is an individual electrode provided for each piezoelectric element 5. A drive signal with a varying voltage is applied to the lower electrode 51. The lower electrode 51 has an elongated shape along the X axis. The plurality of lower electrodes 51 is arranged along the Y axis at intervals. The lower electrode 51 includes a conductive material.

The piezoelectric layer 53 is provided above the lower electrode 51. The piezoelectric layer 53 is, for example, a band-shaped dielectric film that is continuous along the Y axis across the plurality of piezoelectric elements 5. The piezoelectric layer 53 has, for example, a band shape extending along the Y axis, and is separated for each piezoelectric element 5 by forming a plurality of cutouts. The piezoelectric layer 53 is made of a perovskite-type composite oxide.

The upper electrode 52 is provided above the piezoelectric layer 53. The upper electrode 52 is a band-shaped common electrode extending along the Y axis so as to be continuous over the plurality of piezoelectric elements 5. A predetermined reference voltage is applied to the upper electrode 52. The upper electrode 52 includes a conductive material.

A voltage corresponding to a difference between the reference voltage applied to the upper electrode 52 and the drive signal corresponding to the ejection amount supplied to the lower electrode 51 is applied to the piezoelectric layer 53. When a voltage is applied between the lower electrode 51 and the upper electrode 52, the piezoelectric layer 53 is deformed, and thus the piezoelectric element 5 is flexurally deformed, that is, vibrates.

The diaphragm 33 is vibrated by driving the piezoelectric element 5. In the illustrated example, the diaphragm 33 is formed of a stacked body including a first vibrating body layer 331 and a second vibrating body layer 332. The first vibrating body layer 331 is in contact with the pressure chamber substrate 32. The second vibrating body layer 332 is disposed above the first vibrating body layer 331. The first vibrating body layer 331 is formed of an elastic material such as silicon oxide (SiOₓ). The second vibrating body layer 332 is formed of an insulating material such as zirconium oxide (ZrOₓ). The first vibrating body layer 331 is formed by, for example, thermally oxidizing a portion of the pressure chamber substrate 32. The second vibrating body layer 332 is formed by, for example, a known film forming technique such as sputtering. The diaphragm 33 may be formed of one layer or three or more layers.

FIG. 4 shows a neutral axis A1 of the diaphragm 33. The neutral axis A1 is a position at which the compression force and the contraction force are balanced, and is a position at which the stress in the axial direction along the X-Y plane of the diaphragm 33 is 0 (zero).

As shown in FIG. 5, two conductors 381 and 382 are disposed on the upper electrode 52. Each of the conductors 381 and 382 is a band-shaped conductive film that is disposed along the edge in the X1 direction or the X2 direction of the upper electrode 52 and extends in the direction along the Y axis. The conductors 381 and 382 are formed of, for example, a conductive material having an electrically low resistance, such as gold. The conductors 381 and 382 suppress a voltage drop of the reference voltage in the upper electrode 52. In addition, the conductors 381 and 382 also function as a weight for defining a vibration region of the diaphragm 33. The conductors 381 and 382 may be omitted.

Connection wiring 380 is connected to one end of the lower electrode 51 in the longitudinal direction along the X axis. The lower electrode 51 is electrically connected to the wiring board 40 via the connection wiring 380. The upper electrode 52 is electrically connected to the wiring board 40 via wiring (not shown) or the like.

In addition, in the present embodiment, the lower electrode 51 is an individual electrode and the upper electrode 52 is a common electrode, but the lower electrode 51 may be a common electrode, and the upper electrode 52 may be an individual electrode.

FIG. 6 is a diagram schematically illustrating the piezoelectric element 5 illustrated in FIG. 4. As described above, the piezoelectric element 5 includes the lower electrode 51, the piezoelectric layer 53, the upper electrode 52, the first hydrogen absorption layer 54, and the second hydrogen absorption layer 55. Each of the lower electrode 51, the piezoelectric layer 53, and the upper electrode 52 is formed of a plurality of layers. In the present embodiment, the first hydrogen absorption layer 54 is disposed between the lower electrode 51 and the piezoelectric layer 53. The second hydrogen absorption layer 55 is disposed between the plurality of layers constituting the piezoelectric layer 53. Therefore, the second hydrogen absorption layer 55 is disposed inside the piezoelectric layer 53.

The lower electrode 51 includes a first electrode layer 511 and a second electrode layer 512. The first electrode layer 511 is disposed above the diaphragm 33 and is in contact with the diaphragm 33. The first electrode layer 511 includes, for example, platinum (Pt). The thickness of the first electrode layer 511 along the Z axis is not particularly limited, but is, for example, 50 nm or more and 120 nm or less.

The second electrode layer 512 is disposed between the first electrode layer 511 and the first hydrogen absorption layer 54 and is in contact with the first electrode layer 511 and the first hydrogen absorption layer 54. The second electrode layer 512 includes, for example, iridium (Ir). The thickness of the second electrode layer 512 along the Z axis is not particularly limited, but is, for example, 5 nm or more and 50 nm or less. Further, in the present embodiment, the thickness of the second electrode layer 512 is smaller than the thickness of the first electrode layer 511, but may be equal to or larger than the thickness of the first electrode layer 511.

In the present embodiment, the lower electrode 51 is formed of two layers, but may be formed of one layer or three or more layers. In addition, the first electrode layer 511 and the second electrode layer 512 may be formed of a conductive material, and may be formed of a material other than the above-described materials.

The first hydrogen absorption layer 54 has a function to absorb hydrogen present in each layer or between layers constituting the piezoelectric element 5. In particular, the first hydrogen absorption layer 54 suitably absorbs hydrogen in the piezoelectric layer 53, hydrogen in the lower electrode 51, and hydrogen present at the interface of each layer below the piezoelectric layer 53.

In FIG. 6, the interface between the first hydrogen absorption layer 54 and the piezoelectric layer 53 is clearly shown, but may be unclear. For example, a portion of the first hydrogen absorption layer 54 may be embedded in, dispersed in, or integrated with the piezoelectric layer 53. The composition in the first hydrogen absorption layer 54 may be constant or may be graded. Therefore, the piezoelectric layer 53 side and the lower electrode 51 side of the first hydrogen absorption layer 54 may have different compositions. The thickness of the first hydrogen absorption layer 54 along the Z axis is not particularly limited, but is, for example, 2 nm or more and 20 nm or less. The first hydrogen absorption layer 54 may be formed of a plurality of layers.

The piezoelectric layer 53 is a stacked body in which a first layer 531, a second layer 532, a third layer 533, a fourth layer 534, a fifth layer 535, and a sixth layer 536 are stacked in this order. The number of layers included in the piezoelectric layer 53 is not limited to six, and may be five or less or seven or more. However, when the piezoelectric layer 53 is formed of not a single layer but a plurality of layers, the piezoelectric layer 53 having excellent piezoelectric characteristics can be formed.

Each layer constituting the piezoelectric layer 53 is made of a perovskite-type composite oxide. More particularly, each layer contains, for example, lead titanate (PbTiO₃), lead zirconate titanate (PZT: Pb(Zr,Ti)O₃), lead zirconate (PbZrO₃), lead lanthanum titanate ((Pb,La),TiO₃), lead lanthanum zirconate titanate ((Pb,La)(Zr,Ti)O₃), lead zirconate titanate niobate (Pb(Zr,Ti,Nb)O₃), lead zirconate titanate magnesium niobate (Pb(Zr,Ti)(Mg,Nb)O₃), or the like. Each layer constituting the piezoelectric layer 53 may be made of a non-lead material. Examples of the lead-free material include bismuth ferrate (BiFeO₃), barium titanate (BaTiO₃), and potassium sodium niobate ((K,Na)(NbO₃)).

The thickness of each layer of the piezoelectric layer 53 is not particularly limited, but is, for example, 90 nm or more and 250 nm or less.

The first layer 531 is disposed between the first hydrogen absorption layer 54 and the second hydrogen absorption layer 55 and is in contact with the first hydrogen absorption layer 54 and the second hydrogen absorption layer 55. The second hydrogen absorption layer 55 is disposed between the first layer 531 and the second layer 532 and is in contact with the first layer 531 and the second layer 532.

The second hydrogen absorption layer 55 has a function to absorb hydrogen present in each layer or between layers constituting the piezoelectric element 5. In particular, the second hydrogen absorption layer 55 suitably absorbs hydrogen in the first layer 531 and the second layer 532.

In FIG. 6, the interface between the second hydrogen absorption layer 55 and the second layer 532 and the interface between the second hydrogen absorption layer 55 and the first layer 531 are clearly shown, but may not be clear. For example, a portion of the second hydrogen absorption layer 55 may be embedded in, dispersed in, or integrated with the first layer 531 or the second layer 532. In addition, the composition in the second hydrogen absorption layer 55 may be constant or graded. Therefore, the second layer 532 side and the first layer 531 side of the second hydrogen absorption layer 55 may have different compositions. The thickness of the second hydrogen absorption layer 55 along the Z axis is not particularly limited, but is, for example, 2 nm or more and 20 nm or less. In the present embodiment, the thickness D5 of the second hydrogen absorption layer 55 is thinner than the thickness D4 of the first hydrogen absorption layer 54, but may be equal to or larger than the thickness D4 of the first hydrogen absorption layer 54. Further, the second hydrogen absorption layer 55 may be formed of a plurality of layers.

The upper electrode 52 is a structure in which a third electrode layer 521, a fourth electrode layer 522, a fifth electrode layer 523, and a third hydrogen absorption layer 524 are stacked in this order. The third electrode layer 521 is disposed above the piezoelectric layer 53 and is in contact with the sixth layer 536 of the piezoelectric layer 53. The third electrode layer 521 includes, for example, iridium oxide (IrOₓ). The thickness of the third electrode layer 521 along the Z axis is not particularly limited, but is, for example, 5 nm or more and 20 nm or less. The fourth electrode layer 522 includes, for example, titanium oxide (TiOₓ). The thickness of the fourth electrode layer 522 along the Z axis is not particularly limited, but is, for example, 2 nm or more and 20 nm or less. The fifth electrode layer 523 includes, for example, iridium (Ir). The thickness of the fifth electrode layer 523 along the Z axis is not particularly limited, but is, for example, 5 nm or more and 50 nm or less.

The third hydrogen absorption layer 524 includes, for example, titanium (Ti). The thickness of the third hydrogen absorption layer 524 along the Z axis is not particularly limited, but is, for example, 5 nm or more and 20 nm or less. The third hydrogen absorption layer 524 has a function to absorb hydrogen present in each layer or between layers constituting the piezoelectric element 5. In particular, the third hydrogen absorption layer 524 suitably absorbs hydrogen in the upper electrode 52. The composition in the third hydrogen absorption layer 524 may be constant or may be graded. In addition, these may be formed of a plurality of layers.

In the example of FIG. 6, an orientation control layer for controlling the orientation of the piezoelectric layer 53 is not provided between the first hydrogen absorption layer 54 and the piezoelectric layer 53, but the orientation control layer may be provided. The first hydrogen absorption layer 54 may have a function of the orientation control layer. When the first hydrogen absorption layer 54 has the function of the orientation control layer, it is not necessary to separately provide an orientation control layer, and thus manufacturing is easy. For example, the orientation control layer preferentially orients a crystal of an upper layer in a predetermined plane orientation, or adjusts the degree of orientation in a predetermined plane orientation.

Similarly, although an orientation control layer for controlling the orientation of the second layer 532 is not provided between the second hydrogen absorption layer 55 and the second layer 532, the orientation control layer may be provided. The second hydrogen absorption layer 55 may have a function of the orientation control layer. However, when the second hydrogen absorption layer 55 has the function of the orientation control layer, it is not necessary to separately provide an orientation control layer, and thus manufacturing is easy.

### 1-4. Hydrogen Absorption Layer

As described above, the piezoelectric element 5 includes the first hydrogen absorption layer 54. The first hydrogen absorption layer 54 is provided above the lower electrode 51 in the direction along the Z axis which is the stacking direction of the piezoelectric element 5, and has a function to absorb hydrogen. According to the piezoelectric element 5 including the first hydrogen absorption layer 54, it is possible to absorb hydrogen present at the interface between the lower electrode 51 and another layer, hydrogen present in the piezoelectric layer 53, or hydrogen which may enter the piezoelectric layer 53.

Depending on the hydrogen content of the piezoelectric layer 53, the hysteresis characteristics of the piezoelectric element 5 greatly change as compared to a design stage. When the hysteresis characteristics greatly change, there is a concern that the difference in displacement amount increases in the plurality of piezoelectric elements 5. Therefore, in order to reduce the difference in displacement amount between the plurality of piezoelectric elements 5, it is necessary to change the driving voltage and the waveform for each piezoelectric element 5. Adjusting the difference in displacement amount between the plurality of piezoelectric elements 5 in this way is troublesome and inconvenient.

In addition, in a case where the piezoelectric element 5 includes the piezoelectric layer 53 formed of a plurality of layers, the hydrogen content of the piezoelectric layer 53 is likely to be higher than that in the design stage. As will be described later, the piezoelectric layer 53 is formed by repeating film formation and firing of each of a plurality of layers a plurality of times. It is considered that hydrogen enters the piezoelectric layer 53 in this manufacturing process. In addition, not only in the case where the composition in the piezoelectric layer 53 is constant, but also in the case where a composition gradient occurs in the piezoelectric layer 53, a difference in displacement amount occurs between the plurality of piezoelectric elements 5 depending on the hydrogen content of the piezoelectric layer 53.

As described above, the piezoelectric element 5 of the present embodiment includes the first hydrogen absorption layer 54 provided between the lower electrode 51 and the piezoelectric layer 53. Therefore, at the time of manufacturing and using the piezoelectric element 5, hydrogen existing in the piezoelectric layer 53 or hydrogen which may enter the piezoelectric layer 53 can be absorbed. For this reason, it is possible to suppress a large change in the hysteresis characteristics of the piezoelectric element 5 due to the hydrogen content of the piezoelectric layer 53 compared to the design stage. Therefore, it is possible to suppress an increase in the difference in displacement amount due to the change in the hysteresis characteristics in the plurality of piezoelectric elements 5. Therefore, it is not necessary to change the driving voltage and the waveform for each piezoelectric element 5, and it is possible to suppress deterioration in usability. Therefore, the liquid ejection head 3 including the piezoelectric element 5 is excellent in displacement characteristics and usability.

In addition, the first hydrogen absorption layer 54 is provided not above but below the piezoelectric layer 53. It is considered that hydrogen enters the piezoelectric layer 53 from the lower electrode 51 side of the piezoelectric layer 53 during manufacturing in many cases. For this reason, when the first hydrogen absorption layer 54 is provided between the lower electrode 51 and the piezoelectric layer 53, it is possible to reduce a difference in hysteresis characteristics due to a difference in hydrogen content in the plurality of piezoelectric elements 5. In addition, when the first hydrogen absorption layer 54 is provided between the lower electrode 51 and the piezoelectric layer 53, the first hydrogen absorption layer 54 can be disposed closer to the piezoelectric layer 53 than in a case where the first hydrogen absorption layer 54 is provided below the lower electrode 51. Therefore, it is possible to efficiently absorb hydrogen which may enter the piezoelectric layer 53.

The first hydrogen absorption layer 54 is formed of a material capable of absorbing hydrogen. Specifically, the first hydrogen absorption layer 54 includes a hydrogen storage material that can combine with hydrogen to form a hydride. The hydrogen storage material absorbs or releases hydrogen depending on temperature or pressure. When the first hydrogen absorption layer 54 absorbs hydrogen, hydrogen enters gaps in a crystal lattice of the hydrogen storage material. The hydrogen storage material includes a metal such as magnesium (Mg), vanadium (V), lanthanum (La), and titanium (Ti), an alloy including the metal, or a compound including the metal. The first hydrogen absorption layer 54 is formed of, for example, titanium or lead titanate (PbTiO₃). The first hydrogen absorption layer 54 is formed of, for example, a composite oxide containing bismuth (Bi), iron (Fe), titanium (Ti), or lead (Pb).

Similarly, each of the second hydrogen absorption layer 55 and the third hydrogen absorption layer 524 contains a hydrogen storage material that can be combined with hydrogen to form a hydride.

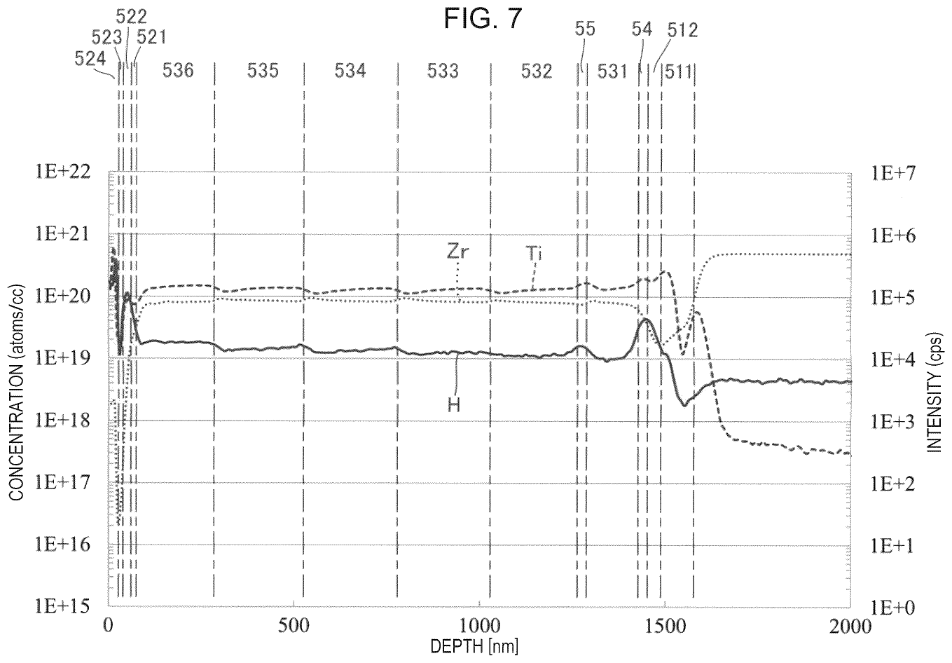

FIG. 7 is a graph showing measurement results for the piezoelectric element 5 of the present embodiment by a secondary ion mass spectrometer (SIMS). In FIG. 7, the material of the first electrode layer 511 is platinum, and the material of the second electrode layer 512 is iridium. The first hydrogen absorption layer 54 contains titanium. The material of each layer of the piezoelectric layer 53 is lead zirconate titanate (PZT). The second hydrogen absorption layer 55 contains titanium. The material of the third electrode layer 521 is iridium oxide, the material of the fourth electrode layer 522 is titanium oxide, the material of the fifth electrode layer 523 is iridium, and the material of the third hydrogen absorption layer 524 is titanium.

The horizontal axis in FIG. 7 represents the depth [nm]. Since analysis is performed in the Z1 direction from the upper electrodes 52, the shallower side is the upper electrode 52 side, and the deeper side is the lower electrode 51 side.

The vertical axis of FIG. 7 represents the hydrogen concentration [atoms/cc]. The concentration of hydrogen is a result of quantification using a standard sample doped with a target element at a known concentration. Note that titanium and zirconium are represented by ion intensity. Further, in FIG. 7, a clear line segment is drawn along the interface of each layer, but the position of the interface slightly deviates depending on the decision made.

As can be seen from FIG. 7, the hydrogen content of the first layer 531 is lower than the hydrogen content of the second layer 532. The first layer 531 is stacked on the first hydrogen absorption layer 54 and is in direct contact with the first hydrogen absorption layer 54. The second layer 532 is stacked above the first layer 531. Therefore, the first layer 531 is provided at a position closer to the first hydrogen absorption layer 54 than the second layer 532. Therefore, due to the function of the first hydrogen absorption layer 54, the hydrogen content of the first layer 531 can be made lower than the hydrogen content of the second layer 532.

The hydrogen content of the first layer 531 may be equal to or higher than the hydrogen content of the second layer 532.

As can be seen from FIG. 7, the hydrogen content of the first hydrogen absorption layer 54 is higher than the hydrogen content of the first layer 531. Since the first hydrogen absorption layer 54 absorbs hydrogen, the hydrogen content of the first layer 531 can be reduced. When the first hydrogen absorption layer 54 is provided, it is possible to suppress entry of hydrogen into the piezoelectric layer 53 including the first layer 531 even after the piezoelectric element 5 is manufactured and when the piezoelectric element 5 is used. In addition, since an increase in the hydrogen content of the first layer 531 is suppressed by the first hydrogen absorption layer 54, an increase in the hydrogen content of each of the second layer 532 to the sixth layer 536 above the first layer 531 can be suppressed.

The first hydrogen absorption layer 54 is provided on the lower electrode 51. Furthermore, the first hydrogen absorption layer 54 is preferably provided not only above the lower electrode 51 but also on a portion of the diaphragm 33 shown in FIG. 4 above which the lower electrode 51 is not provided, that is, on the diaphragm 33. Since the first hydrogen absorption layer 54 is provided in this manner, the entire lower surface of the first layer 531 is in contact with the first hydrogen absorption layer 54. Therefore, as compared to a configuration in which only a portion of the lower surface of the first layer 531 is in contact with the first hydrogen absorption layer 54, an increase in the hydrogen content of the first layer 531 can be suppressed by the function of the first hydrogen absorption layer 54.

The hydrogen content of the first hydrogen absorption layer 54 may be equal to or lower than the hydrogen content of the first layer 531.

The first hydrogen absorption layer 54 has a higher hydrogen absorption property than the lower electrode 51. A high hydrogen absorption property means that a material easily combines with hydrogen to form a hydride. Therefore, the lower electrode 51 is less susceptible to hydrogenation than the first hydrogen absorption layer 54. For example, the first hydrogen absorption layer 54 and the lower electrode 51 include a metal. However, the first hydrogen absorption layer 54 has an excellent hydrogen absorbing property, and is provided separately from the lower electrode 51. That is, the lower electrode 51 includes a metal similarly to the first hydrogen absorption layer 54, but does not need to be a hydrogen storage material. Further, the lower electrode 51 may include a hydrogen storage material. Even in this case, the first hydrogen absorption layer 54 is superior to the lower electrode 51 in the hydrogen absorbing property. Since the first hydrogen absorption layer 54 is provided in order to reduce the hydrogen content of the piezoelectric layer 53, an effect of suppressing a decrease in hysteresis characteristics in the plurality of piezoelectric elements 5 described above is exhibited.

As described above, the piezoelectric element 5 includes the second hydrogen absorption layer 55. The second hydrogen absorption layer 55 is provided above the first layer 531 in the direction along the Z axis which is the stacking direction of the piezoelectric element 5, and has a function to absorb hydrogen. When the second hydrogen absorption layer 55 is provided, it is possible to further reduce the hydrogen content of the piezoelectric layer 53 compared to a case where the second hydrogen absorption layer 55 is not provided.

The second hydrogen absorption layer 55 may be omitted as appropriate.

The hydrogen content of the second layer 532 of the piezoelectric layer 53 is smaller than the hydrogen content of the third layer 533. The second layer 532 is stacked on the second hydrogen absorption layer 55 and is in contact with the second hydrogen absorption layer 55. The third layer 533 is stacked above the second layer 532. Therefore, the second layer 532 is disposed closer to the second hydrogen absorption layer 55 than the third layer 533. Therefore, the hydrogen content of the second layer 532 can be reduced by the function of the second hydrogen absorption layer 55 to absorb hydrogen.

As can be seen from FIG. 7, the hydrogen content of the second hydrogen absorption layer 55 is lower than the hydrogen content of the first hydrogen absorption layer 54. When the second hydrogen absorption layer 55 is provided, it is possible to further reduce the hydrogen content of the piezoelectric layer 53 compared to a case where the second hydrogen absorption layer 55 is not provided. Even if the first hydrogen absorption layer 54 alone cannot sufficiently absorb hydrogen, when the second hydrogen absorption layer 55 is provided, an increase in the hydrogen content in the central portion of the piezoelectric layer 53 can be more effectively suppressed. Therefore, it is possible to effectively suppress a decrease in the displacement characteristics of the piezoelectric element 5.

Even in a case where the first hydrogen absorption layer 54 is provided alone, it is considered that hydrogen can be sufficiently absorbed by the first hydrogen absorption layer 54. In addition, much hydrogen enters from the piezoelectric layer 53 from the lower electrode 51 side. Therefore, it is considered that the hydrogen content of the second hydrogen absorption layer 55 is lower than the hydrogen content of the first hydrogen absorption layer 54.

The hydrogen content of the second hydrogen absorption layer 55 may be equal to or higher than the hydrogen content of the first hydrogen absorption layer 54.

In the present embodiment, in the direction along the Z axis, the thickness D5 of the second hydrogen absorption layer 55 is thinner than the thickness D4 of the first hydrogen absorption layer 54. Therefore, the thickness D4 is thicker than the thickness D5. When the thickness D4 is thicker than the thickness D5, it is possible to suppress entry of hydrogen into the piezoelectric layer 53 from the lower electrode 51 side through the first hydrogen absorption layer 54, compared to a case where the thickness D4 is thinner than the thickness D5.

The thickness D5 of the second hydrogen absorption layer 55 may be equal to or larger than the thickness D4 of the first hydrogen absorption layer 54.

As shown in FIG. 7, when peak values of hydrogen at the position of the first hydrogen absorption layer 54 and at the position of the second hydrogen absorption layer 55 are measured by an SIMS, the peak value at the position of the second hydrogen absorption layer 55 with respect to the peak value at the position of the first hydrogen absorption layer 54 is preferably 0.3 or more and 0.5 or less. In the example of FIG. 7, the peak value at the position of the second hydrogen absorption layer 55 with respect to the peak value at the position of the first hydrogen absorption layer 54 is 0.3 or more and 0.5 or less.

Due to a measurement error of an SIMS, an interface effect, or the like, the peak position may be shifted with respect to the depth at which each of the first hydrogen absorption layer 54 and the second hydrogen absorption layer 55 is located. In this case, the peak of hydrogen observed in the vicinity of the depth at which each of the first hydrogen absorption layer 54 and the second hydrogen absorption layer 55 is located is regarded as the peak value in each of the first hydrogen absorption layer 54 and the second hydrogen absorption layer 55.

When the peak value relationship is equal to or greater than the lower limit value described above, the second hydrogen absorption layer 55 can sufficiently absorb hydrogen that has not been absorbed by the first hydrogen absorption layer 54, as compared to a case where the peak value relationship is less than the lower limit value.

When the peak value relationship is equal to or less than the upper limit value described above, it is not necessary to excessively increase the thickness D5 of the second hydrogen absorption layer 55, for example, as compared to a case where the peak value relationship exceeds the upper limit value. Therefore, it is possible to suppress the possibility that the displacement amount of the piezoelectric layer 53 decreases because of the presence of the second hydrogen absorption layer 55.

From the viewpoint of significantly exerting the effect, the peak value at the position of the second hydrogen absorption layer 55 with respect to the peak value at the position of the first hydrogen absorption layer 54 is more preferably 0.30 or more and 0.46 or less.

As shown in FIG. 7, the variation with respect to the average value of the hydrogen content at the central portion in the stacking direction of the piezoelectric element 5 is preferably 24% or less. The central portion is a layer located at the center of the piezoelectric layer 53 in the stacking direction and is not in contact with a layer other than the piezoelectric layer 53. The central portion is the third layer 533 and the fourth layer 534 in the example of FIG. 6. These layers are not in contact with the second hydrogen absorption layer 55 and the upper electrode 52, which are layers other than the piezoelectric layer 53.

In the example of FIG. 7, the variation is 24% or less. When the variation is 24% or less, it is possible to reduce the likelihood that the slope of a hysteresis curve indicating the relationship between the voltage and the polarization of the piezoelectric layer 53 becomes steep, as compared to a case where the variation exceeds 24%. In addition, it is possible to reduce the likelihood that the shape of the hysteresis curve changes over time from the time of design. Therefore, it is possible to suppress a decrease in the displacement characteristics of the piezoelectric element 5. The variation of the hydrogen content in the central portion with respect to the average value may exceed 24%.

In addition, as shown in FIG. 7, the hydrogen content of each of the third layer 533 and the fourth layer 534 which are the central portion of the piezoelectric layer 53 is suppressed similarly to the hydrogen content of the first layer 531. Specifically, the average hydrogen content of each layer in the central portion of the piezoelectric layer 53 is preferably less than 1E+20 [atoms/cc], and more preferably less than 1E+19 [atoms/cc]. Note that “E” represents a power of 10. For example, 1E+20 represents 1×10²⁰, and 1E+19 represents 1×10¹⁹. The performance of the piezoelectric element 5 is improved as the range of layers away from a neutral axis A1 of the piezoelectric layers 53 shown in FIG. 4 is increased. The third layer 533 and the fourth layer 534 are more distant from the neutral axis A1 than the first layer 531. By reducing the hydrogen content of each of the third layer 533 and the fourth layer 534 away from the neutral axis A1, it is possible to suppress a decrease in the displacement characteristics of the piezoelectric element 5.

As described above, the upper electrode 52 includes the third hydrogen absorption layer 524. The third hydrogen absorption layer 524 is provided on the upper electrode 52 side with respect to the piezoelectric layer 53, and is provided as the uppermost layer of the upper electrode 52. The third hydrogen absorption layer 524 has a function to absorb hydrogen. When the third hydrogen absorption layer 524 is provided, it is possible to suppress entry of hydrogen into the piezoelectric layer 53 from the upper electrode 52 side, compared to a case where the third hydrogen absorption layer 524 is not provided. In addition, the hydrogen content of each of the third electrode layer 521 to the fifth electrode layer 523 can be reduced.

The fourth electrode layer 522 described above may have a function as a hydrogen absorption layer that absorbs hydrogen. When the fourth electrode layer 522 has the function as a hydrogen absorption layer, it is possible to more effectively suppress entry of hydrogen into the piezoelectric layer 53 from the upper electrode 52 side. In addition, the hydrogen content of each of the third electrode layer 521 to the fifth electrode layer 523 can be further reduced. In the present embodiment, the material of the third hydrogen absorption layer 524 is titanium, and the material of the fourth electrode layer 522 is titanium oxide. However, the third hydrogen absorption layer 524 and the fourth electrode layer 522 may be made of the same material or different materials.

As described above, the piezoelectric layer 53 is formed of a perovskite-type composite oxide, and is preferably formed of lead zirconate titanate (PZT). When the piezoelectric layer 53 is formed of PZT, the effect of suppressing a change in the hysteresis characteristics of the piezoelectric element 5 provided by providing the first hydrogen absorption layer 54 is particularly remarkably exhibited. Furthermore, in the case where the piezoelectric layer 53 is formed of a plurality of layers, the effect provided by providing the first hydrogen absorption layer 54 can be particularly remarkably exhibited.

It is particularly preferable that each of the first hydrogen absorption layer 54, the second hydrogen absorption layer 55, and the third hydrogen absorption layer 524 contain titanium. Furthermore, each of these layers is preferably formed of titanium. Titanium is excellent in hydrogen absorption performance. Therefore, when these layers include titanium, it is possible to absorb a larger amount of hydrogen which may enter the piezoelectric layer 53, compared to a case where these layers do not include titanium.

### 1-5. Method of Manufacturing Piezoelectric Element 5

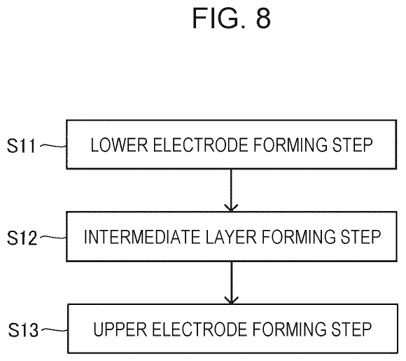

FIG. 8 is a flowchart of a method of manufacturing the piezoelectric element 5 of FIG. 6. As illustrated in FIG. 8, the method of manufacturing the piezoelectric element 5 includes a lower electrode forming step S11, an intermediate layer forming step S12, and an upper electrode forming step S13. These steps are performed in this order.

In the lower electrode forming step S11, the lower electrode 51 is formed. The lower electrode forming step S11 includes formation of the first electrode layer 511 and formation of the second electrode layer 512. Specifically, first, for example, the first electrode layer 511 is formed by forming a layer including a conductive material such as platinum on the diaphragm 33 using a sputtering method, an evaporation method, or a chemical vapor deposition (CVD) method, for example. Next, for example, a layer including a conductive material such as iridium is formed on the first electrode layer 511 by a sputtering method, an evaporation method, or a CVD method to form the second electrode layer 512.

The intermediate layer forming step S12 includes formation of the first hydrogen absorption layer 54, formation of the piezoelectric layer 53, and formation of the second hydrogen absorption layer. Specifically, first, a layer including a hydrogen storage material such as titanium is formed on the lower electrode 51 by a sputtering method, an evaporation method, or a CVD method. Next, a first layer precursor made of a perovskite-type composite oxide such as PZT is formed on the layer including the hydrogen storage material by using a sol-gel method. Next, the layer including the hydrogen storage material and the first layer precursor are fired. As a result, the first hydrogen absorption layer 54 and the first layer 531 are formed.

Next, another layer including a hydrogen storage material such as titanium is formed on the first layer 531 by a sputtering method, an evaporation method, or a CVD method. Next, a second layer precursor made of a perovskite-type composite oxide such as PZT is formed on the other layer including the hydrogen storage material by using a sol-gel method. Next, the other layer including the hydrogen storage material and the second layer precursor are fired. As a result, the second hydrogen absorption layer 55 and the second layer 532 are formed.

When the second hydrogen absorption layer 55 is formed, the second hydrogen absorption layer 55 may be formed in a state where moisture remains on the surface of the first layer 531. For this reason, it is preferable to perform a heating step for removing moisture on the surface in the formation of the second hydrogen absorption layer 55. Thus, the moisture remaining on the surface of the first layer 531 can be reduced. Therefore, the amount of hydrogen absorbed by the second hydrogen absorption layer 55 when the second hydrogen absorption layer 55 is formed is reduced, so that the formed second hydrogen absorption layer 55 can sufficiently absorb hydrogen.

Next, a third layer precursor made of a perovskite-type composite oxide such as PZT is formed on the second layer 532 by using a sol-gel method, and then the third layer precursor is fired. Thus, the third layer 533 is formed. The fourth layer 534, the fifth layer 535, and the sixth layer 536 are formed in the same manner. Next, after the formation of the sixth layer 536, the first hydrogen absorption layer 54, the second hydrogen absorption layer 55, and the piezoelectric layer 53 are collectively fired.

When each layer of the piezoelectric layer 53 is formed by a sol-gel method, the shape and crystallinity of a lower layer affect the shape and crystallinity of an upper layer. In the present embodiment, the hydrogen content of the second layer 532 is smaller than the hydrogen content of the third layer 533. Therefore, it is possible to suppress the influence of the shape and crystallinity of the second layer 532 on the third layer 533 at the stage of forming the third layer 533, which is an intermediate layer portion of the piezoelectric layer 53, by a sol-gel method.

In the upper electrode forming step S13, the upper electrode 52 is formed. The upper electrode forming step S13 includes formation of the third electrode layer 521, formation of the fourth electrode layer 522, formation of the fifth electrode layer 523, and formation of the third hydrogen absorption layer 524. Specifically, for example, a layer including a conductive material such as iridium is formed on the sixth layer 536 by a sputtering method, an evaporation method, or a CVD method, and then fired, thereby forming the third electrode layer 521 including a metal oxide or the like. Next, a layer including a conductive material such as titanium is formed on the third electrode layer 521 by a sputtering method, an evaporation method, or a CVD method and then fired, thereby forming the fourth electrode layer 522 including a metal oxide or the like.

Next, a layer including a conductive material such as iridium is formed on the fourth electrode layer 522 by a sputtering method, an evaporation method, or a CVD method, thereby forming the fifth electrode layer 523. Next, a layer including a hydrogen storage material such as titanium is formed on the fifth electrode layer 523 by a sputtering method, an evaporation method, or a CVD method, thereby forming the third hydrogen absorption layer 524. Thus, the piezoelectric element 5 is manufactured.

### 2. Modifications

The embodiments described above may be modified in various ways. Specific modifications that can be applied to the embodiments described above will be described below. Any two or more selected from the following modifications can be appropriately combined as long as the two or more modifications do not contradict each other.

### 2-1. First Modification

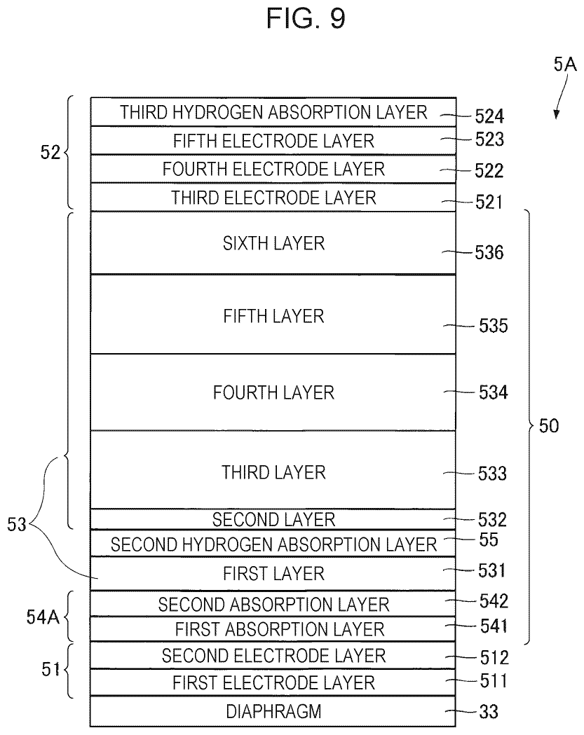

FIG. 9 is a diagram schematically illustrating a piezoelectric element 5A of a first modification. As illustrated in FIG. 9, a first hydrogen absorption layer 54A of the piezoelectric element 5A of the first modification includes a plurality of layers having different constituent elements. Specifically, the first hydrogen absorption layer 54A includes a first absorption layer 541 and a second absorption layer 542. The first absorption layer 541 is formed of, for example, titanium. The second absorption layer 542 is formed of, for example, lead zirconate (PbZrO₃) or lead titanate (PbTiO₃).

When the first hydrogen absorption layer 54A is formed of a plurality of layers, it is possible to more effectively suppress entry of hydrogen into the piezoelectric layer 53, compared to a single layer.

In addition, the first absorption layer 541 and the second absorption layer 542 may be different from or the same as each other in hydrogen absorption performance, that is, the amount of hydrogen absorbed. The second absorption layer 542 may function as the above-described orientation control layer.

In the first embodiment and the first modification, a portion of the lower electrode 51 may be regarded as a portion of the first hydrogen absorption layer 54. In this case, the first hydrogen absorption layer 54 is also regarded as including a plurality of layers. For example, the second electrode layer 512 of the lower electrode 51 may be regarded as a portion of the first hydrogen absorption layer 54. The first hydrogen absorption layer 54 may have a function as an electrode.

### 2-2. Second Modification

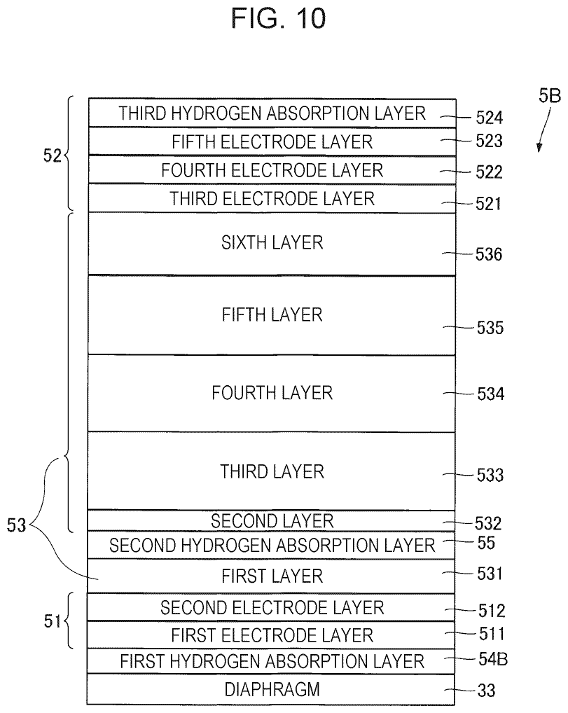

FIG. 10 is a diagram schematically illustrating a piezoelectric element 5B of a second modification. As illustrated in FIG. 10, the first hydrogen absorption layer 54B of the second modification is provided below the lower electrode 51 in the direction along the Z axis which is the stacking direction. The first hydrogen absorption layer 54B is disposed between and in contact with the diaphragm 33 and the lower electrode 51.

When the first hydrogen absorption layer 54B is disposed below the lower electrode 51, it is possible to suppress entry of hydrogen into the piezoelectric layer 53 from the diaphragm 33 side.

### 2-3. Third Modification

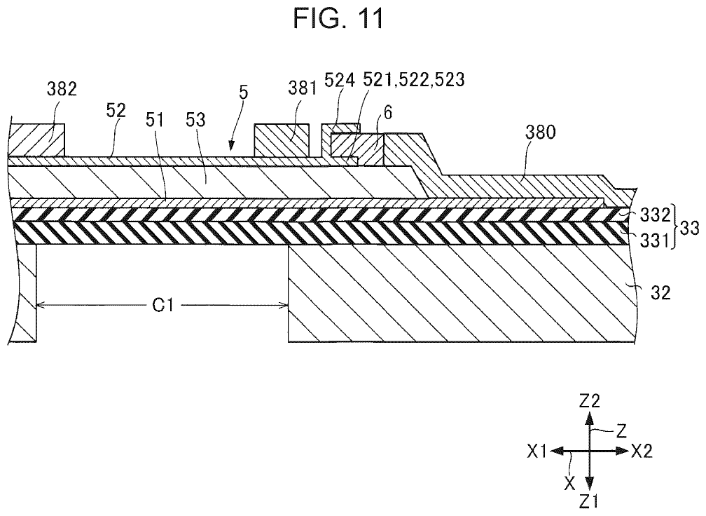

FIG. 11 is a cross-sectional view of a piezoelectric element 5 of a third modification. As illustrated in FIG. 11, a protective film 6 is disposed on the top surface of the piezoelectric layer 53. Specifically, the protective film 6 is disposed on one end portion of the piezoelectric layer 53 along the X axis. A portion of the top surface of the piezoelectric layer 53 is not covered with the upper electrode 52 and is exposed. A protective film 6 is disposed on the exposed portion. The protective film 6 includes, for example, a ceramic such as aluminum oxide (AlOₓ) or silicon nitride.

When the protective film 6 is provided on the exposed portion of the piezoelectric layer 53, entry of hydrogen into the piezoelectric layer 53 can be suppressed. A portion of the protective film 6 is sandwiched by the upper electrode 52. Specifically, the third electrode layer 521, the fourth electrode layer 522, and the fifth electrode layer 523 are disposed below the protective film 6. The third hydrogen absorption layer 524 is disposed above the protective film 6. When a portion of the third hydrogen absorption layer 524 is provided on the protective film 6, hydrogen in the protective film 6 can be absorbed by the third hydrogen absorption layer 524, and entry of hydrogen from the protective film 6 into the piezoelectric layer 53 can be suppressed.

The third hydrogen absorption layer 524 may be disposed below the protective film 6. The third hydrogen absorption layer 524 is provided on a portion of the top surface of the protective film 6, but may be provided on the entire top surface of the protective film 6.

In the case where the protective film 6 is provided, the protective film 6 is formed during the formation of the third hydrogen absorption layer 524 after the third electrode layer 521, the fourth electrode layer 522, and the fifth electrode layer 523 are formed in the method of manufacturing the piezoelectric element 5. The protective film 6 is mainly formed on an exposed portion of the top surface of the piezoelectric layer 53 where the third electrode layer 521, the fourth electrode layer 522, and the fifth electrode layer 523 are not provided. The protective film 6 is formed by forming a film of a ceramic material using a sputtering method, an evaporation method, or a CVD method.

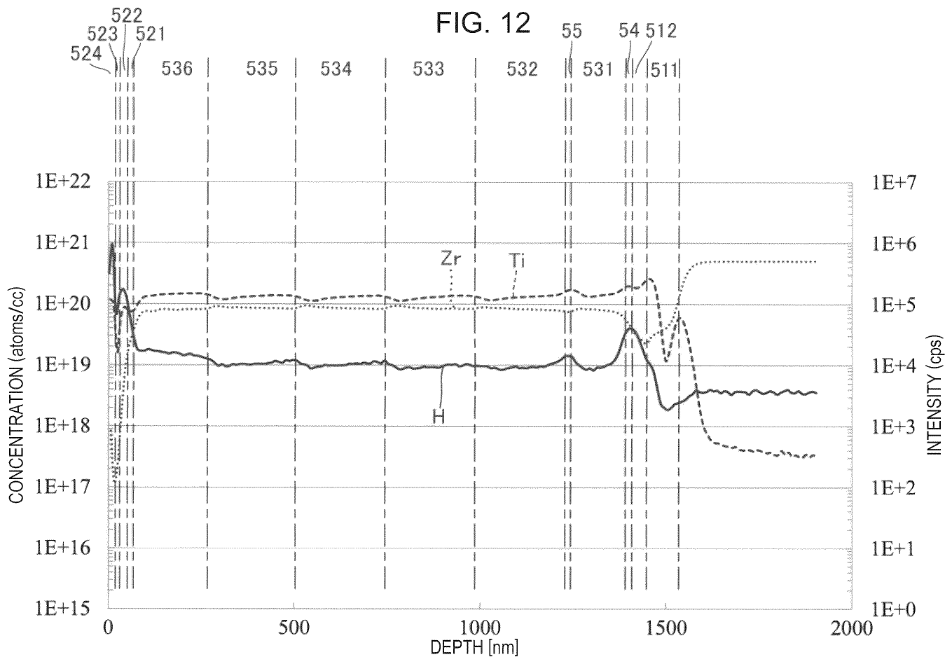

FIG. 12 is a graph showing measurement results for the piezoelectric element of the third modification by a secondary ion mass spectrometer. As can be seen from FIG. 12, also in this modification, the hydrogen content of the first layer 531 is lower than the hydrogen content of the second layer 532, as in the first embodiment. The hydrogen content of the first hydrogen absorption layer 54 is higher than the hydrogen content of the first layer 531. The hydrogen content of the second hydrogen absorption layer 55 is lower than the hydrogen content of the first hydrogen absorption layer 54.

In the example of FIG. 12, the peak value at the position of the second hydrogen absorption layer 55 with respect to the peak value at the position of the first hydrogen absorption layer 54 is 0.3 or more and 0.5 or less. Further, in the example of FIG. 12, the variation with respect to the average value of the hydrogen content at the central portion in the stacking direction of the piezoelectric element 5 is preferably 24% or less.

### 2-4. Fourth Modification

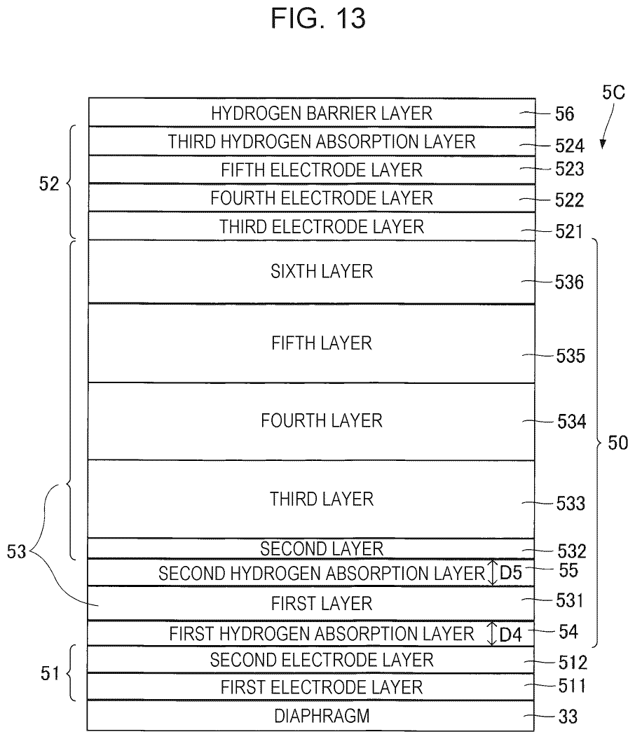

FIG. 13 is a diagram schematically illustrating a piezoelectric element 5C of a fourth modification. As illustrated in FIG. 13, the piezoelectric element 5C of the fourth modification has a hydrogen barrier layer 56 that suppresses entry of hydrogen as the uppermost layer in the stacking direction. The hydrogen barrier layer 56 includes, for example, a ceramic such as aluminum oxide (AlOₓ) or silicon nitride. By providing the hydrogen barrier layer 56, it is possible to suppress entry of external hydrogen into the piezoelectric layer 53 compared to a case where the hydrogen barrier layer 56 is not provided.

### 2-5. Other Modifications

The “liquid ejection head” may be a circulation type head having a so-called circulation flow path.

The “image forming apparatus” may be employed for various apparatuses such as a facsimile apparatus and a copy machine in addition to an apparatus dedicated to printing. The use of the image forming apparatus is not limited to printing. For example, an image forming apparatus that ejects a solution of a coloring material is used as a manufacturing apparatus that forms a color filter of a display device such as a liquid crystal display panel. In addition, an image forming apparatus that ejects a solution of a conductive material is used as a manufacturing apparatus which forms wiring or an electrode of a wiring board. In addition, an image forming apparatus that ejects a solution of an organic substance relating to a living body is used as, for example, a manufacturing apparatus that manufactures a biochip.

Although the present disclosure is described above based on the preferred embodiments, the present disclosure is not limited to the above-described embodiments. The configuration of each component of the present disclosure can be replaced with any configuration having the same function as in the above-described embodiments, and any configuration can be added.

What is claimed is:

1. A piezoelectric element, comprising:
a lower electrode, a piezoelectric layer including a perovskite-type composite oxide, and an upper electrode that are stacked in a stacking direction; and
a first hydrogen absorption layer that absorbs hydrogen above or below the lower electrode in the stacking direction.

2. The piezoelectric element according to claim 1, wherein
the first hydrogen absorption layer is provided between the lower electrode and the piezoelectric layer in the stacking direction.

3. The piezoelectric element according to claim 2, wherein
the piezoelectric layer includes a plurality of layers including a first layer stacked above the first hydrogen absorption layer, and a second layer stacked above the first layer, and
a hydrogen content of the first layer is lower than a hydrogen content of the second layer.

4. The piezoelectric element according to claim 3, wherein
a hydrogen content of the first hydrogen absorption layer is higher than the hydrogen content of the first layer.

5. The piezoelectric element according to claim 1, wherein
the first hydrogen absorption layer includes a plurality of layers having different constituent elements.

6. The piezoelectric element according to claim 1, wherein
the piezoelectric layer includes a plurality of layers including a first layer stacked above the first hydrogen absorption layer,
the piezoelectric element further comprising a second hydrogen absorption layer that absorbs hydrogen above the first layer in the stacking direction.

7. The piezoelectric element according to claim 6, wherein
the piezoelectric layer includes a plurality of layers including a second layer stacked above the second hydrogen absorption layer, and a third layer stacked above the second layer, and
a hydrogen content of the second layer is higher than a hydrogen content of the third layer.

8. The piezoelectric element according to claim 6, wherein
a hydrogen content of the second hydrogen absorption layer is lower than a hydrogen content of the first hydrogen absorption layer.

9. The piezoelectric element according to claim 8, wherein
a thickness of the second hydrogen absorption layer is thinner than a thickness of the first hydrogen absorption layer in the stacking direction.

10. The piezoelectric element according to claim 6, wherein
when peak values of hydrogen at a position of the first hydrogen absorption layer and at a position of the second hydrogen absorption layer are measured by a secondary ion mass spectrometer, the peak value at the position of the second hydrogen absorption layer with respect to the peak value at the position of the first hydrogen absorption layer is 0.3 or more and 0.5 or less.

11. The piezoelectric element according to claim 1, wherein
the first hydrogen absorption layer is provided below the lower electrode in the stacking direction.

12. The piezoelectric element according to claim 1, wherein
the first hydrogen absorption layer has a higher hydrogen absorption property than the lower electrode.

13. The piezoelectric element according to claim 1, wherein
the upper electrode has a third hydrogen absorption layer that absorbs hydrogen.

14. The piezoelectric element according to claim 6, wherein
the piezoelectric layer includes a plurality of layers, and
a variation with respect to an average value of a hydrogen content at a central portion in the stacking direction of the piezoelectric layer is 24% or less.

15. The piezoelectric element according to claim 1, wherein
the piezoelectric layer includes lead zirconate titanate.

16. A liquid ejection head, comprising the piezoelectric element according to claim 1.
